(19) United States
(12) Patent Application Publication
(10) Pub. No.: US 2026/0271248 A1
(43) Pub. Date: Sep. 10, 2026

(54) AIR COOLING OF A RECHARGEABLE BATTERY BLOCK BY MEANS OF A CHARGING DEVICE

(71) Applicant: WÜRTH INTERNATIONAL AG, Chur (CH)

(72) Inventors: Dirk FÖRSTNER, Weinstadt (DE); Heiko ROSSKAMP, Adelberg (DE); Jonas HOG, Schwäbisch Hall (DE)

(21) Appl. No.: 19/162,557

(22) PCT Filed: Mar. 8, 2024
(86) PCT No.: PCT/EP2024/056223

§ 371 Date: Sep. 5, 2025

(30) Foreign Application Priority Data
Mar. 10, 2023 (DE) 10 2023 106 069.4

(51) Int. Cl. H05K 7/20; H02J 7/70

(52) U.S. Cl. CPC H05K 7/20909; H02J 7/70; H05K 7/20172

(57) ABSTRACT

Charging device for charging a battery pack for a hand-held device, the charging device comprising a charging housing, a receiving device provided on the charging housing for receiving the battery pack for charging, an air conveying device in and/or on the charging housing for conveying air, and a closed air guiding channel which extends from the receiving device through an interior of the charging housing, so that air can be guided through the battery pack and/or past the battery pack and through the interior of the air guiding channel by means of the air conveying device.

### CROSS-REFERENCE TO RELATED APPLICATION

This application is a national stage application, filed under 35 U.S.C. § 371, of International Patent Application No. PCT/EP 2024/056223, filed on Mar. 8, 2024, claiming priority of the German patent application DE 10 2023 106 069.4, filed on Mar. 10, 2023, both being incorporated by reference herein in its entirety.

### FIELD OF THE DISCLOSURE

The disclosure relates to a charging device, a charging arrangement, a battery pack and a method for charging a battery pack.

### Technical Background

During the charging of a battery pack of a hand-held device (for example an electric drilling machine), a considerable heat development occurs, which limits the possible charging power and therefore leads to a long charging process.

DE 102004020147 B4, DE 102015002285 A1, DE 102018204761 A1 and WO 2019/005765 A1 disclose charging devices for battery packs with air cooling. However, the charging time is still limited in a negative manner by heat development during the charging of a battery pack. Furthermore, contamination can occur as a result of air cooling of a battery pack.

There may be a need to enable rapid charging of a battery pack by means of a charging device without excessive contamination.

### SUMMARY OF THE DISCLOSURE

This need is met by the subject matters having the features according to the independent patent claims. Further exemplary embodiments are shown in the dependent claims.

### DESCRIPTION OF EXEMPLARY EMBODIMENTS

According to one exemplary embodiment of the present disclosure, a charging device for charging a battery pack for a hand-held device is provided, the charging device comprising a charging housing, a receiving device provided on the charging housing for receiving the battery pack for charging, an air conveying device in and/or on the charging housing for conveying air, and a closed air guiding channel which extends from the receiving device through an interior of the charging housing, so that air can be guided through the battery pack and/or past the battery pack and through the interior of the air guiding channel by means of the air conveying device (in particular during charging, before charging and/or after charging).

According to a further exemplary embodiment of the present disclosure, a charging arrangement is provided which comprises a battery pack (for example a battery pack having the features described below) for a hand-held device and a charging device having the features described above for charging the battery pack when the battery pack is received on the receiving device, wherein (in particular during charging, before charging and/or after charging) air can be guided through the battery pack and/or past the battery pack and through the interior of the air guiding channel by means of the air conveying device.

According to a further exemplary embodiment of the disclosure, a battery pack for a hand-held device is provided which can be charged with a charging device (for example with a charging device having the features described above), the battery pack comprising electrical contacts for charging the battery pack when the battery pack is received on a receiving device of the charging device, a battery housing with at least one battery air supply opening and with at least one battery air discharge opening which are configured such that (in particular during charging, before charging and/or after charging) air can be guided through the at least one battery air supply opening into the battery housing, through the interior of the battery housing and through the at least one battery air discharge opening out of the battery housing and into the charging device by means of an air conveying device of the charging device, and a dirt collecting pocket in the battery housing adjacent to the at least one battery air supply opening for collecting dirt guided into the battery housing with the air.

According to a further exemplary embodiment of the disclosure, a method for charging a battery pack for a hand-held device by means of a charging device is provided, the method comprising receiving the battery pack for charging on a receiving device of the charging device provided on a charging housing, and conveying air by means of an air conveying device of the charging device in and/or on the charging housing along a fully circumferentially closed air guiding channel which extends from the receiving device through an interior of the charging housing, so that air is guided through the battery pack and/or past the battery pack and through the interior of the air guiding channel by means of the air conveying device (in particular during charging, before charging and/or after charging).

In the context of the present application, a “charging device” can be understood in particular as a device which can be configured for electrically charging a completely or partially discharged battery pack. The charging device can, for example, draw electrical charging energy from a power grid. The charging device can electrically charge a battery pack received thereon when corresponding electrically conductive electrical contacts of the charging device and battery pack are brought into electrically conductive contact with one another.

In the context of the present application, a “battery pack” can be understood in particular as an electrical energy supply device which can supply a hand-held device (for example an electric hand-held device such as a drilling machine) which can be coupled to the battery pack with electrical energy. For this purpose, a battery pack can comprise a battery cell or a plurality of battery cells. Preferably, the battery pack can be rechargeable, i.e., for example, can be recharged after discharging by connection to a charging device.

In the context of the present application, a “hand-held device” can be understood in particular as a portable device which can be manually operated and carried by a user and with which a hand-held task can be performed, for example working on a subsurface. Advantageously, the hand-held device can be an electric hand-held device which can be operated by means of an electrically generated driving force. Such an electric hand-held device can be controlled by means of electrical control signals. In particular, by means of a hand-held device and by applying a driving force in the form of a longitudinal force and/or a torque, a hole can be drilled in a subsurface and/or a driving force in the form of a longitudinal force and/or a torque can be applied to a fastening element to be placed in a subsurface. For example, the hand-held device can be configured to rotationally drive a working device and thus a drill and/or a fastening element. Examples of electric or motorized hand-held devices are a cordless screwdriver, a cordless drilling screwdriver, a rotary screwdriver, a pulse screwdriver, a ratchet screwdriver, a drilling machine, a percussion screwdriver (in particular a cordless percussion screwdriver) and a hammer drill.

In the context of the present application, a “receiving device for receiving a battery pack” can be understood in particular as an electromechanical interface of a charging device which is configured to (for example positively lock) mechanical receive of a battery pack while forming an electrical connection between the battery pack and the receiving device. Preferably, at least one opening can be formed in the charging housing in the region of the receiving device, through which opening air for cooling the battery pack can be guided before and/or during charging.

In the context of the present application, an “air conveying device” can be understood in particular as a component or an assembly which is configured to convey air. For conveying air, the air conveying device can be supplied with electrical energy, for example from a power grid or a battery. For example, an air conveying device can comprise one or more fans.

In the context of the present application, a “closed air guiding channel” can be understood in particular as a physical structure in an interior of the charging housing which defines an air guiding path along which the air can flow through the charging housing. By the air guiding channel being open on the input side and on the output side and being closed on the shell side, a flow of air from the interior of the air guiding channel into other regions of the charging housing interior of the charging device can be prevented. Preferably, the air guiding channel is closed over the entire circumference and extends continuously between at least one charging air supply opening and at least one charging air discharge opening of a charging device. By means of such an air guiding channel, it can be made impossible for (for example dirt-laden) air to come into physical contact with charging electronics when flowing through the charging device.

In the context of the present application, a “dirt collecting pocket in a battery pack housing” can be understood in particular as a cavity in the interior of the battery pack housing which is in fluid connection with air guided through the battery pack housing. If air flows through the battery pack housing from at least one battery pack air supply opening to at least one battery pack air discharge opening, it-preferably directly-after flowing into the battery pack air supply opening comes into operative connection with the dirt collecting pocket, such that dirt possibly carried along with the air can be fully or partially received in the dirt collecting pocket. Clearly, dirt-laden air can be depleted with a dirt collecting pocket.

In the context of the present application, a “main surface” can be understood in particular as one of two opposite surfaces of the charging housing or of the battery pack housing which form the two largest surfaces of the charging housing or of the battery pack housing. The two main surfaces of the charging housing or of the battery pack housing are located between the smaller-area side walls of the charging housing or of the battery pack housing. A main surface can form in particular a top side or a bottom side of the charging housing or of the battery pack housing, for example if the charging device is arranged on a horizontal surface (for example a table) or the battery pack block is arranged on a horizontally oriented charging device. If the charging device is mounted on a vertical surface (for example on a wall), the mounting surface for wall mounting and a battery receiving surface opposite thereto form the two main surfaces of the charging housing. One of the main surfaces of the charging housing can thus be a standing surface or a fastening surface, whereas the opposite other main surface can form the battery receiving surface. In the battery pack housing, one of the main surfaces can be a charging side facing the charging device during charging.

According to an exemplary embodiment, a charging device for charging a battery pack is provided in which a receiving device is formed on a charging housing, on which receiving device a battery pack to be electrically charged can be electromechanically received. An air conveying device can be mounted in the charging housing in order to suck or push air through the battery pack and subsequently through a closed air guiding channel in the interior of the charging housing. This measure brings about efficient cooling of the interior of the battery pack by a cooling air flow. As a result, the temperature of the battery pack during charging can be kept sufficiently low and/or can be lowered before the charging after prior use of the battery pack in order to enable a rapid and reliable charging process. During use of the battery pack before the charging, for example in conjunction with a hand-held device, and/or during the electrical charging of a completely or partially emptied battery pack, a strong heat development can occur, which limits the speed of a reliable charging process.

The charging speed can thus be increased by active cooling of the battery pack. This can advantageously succeed without the risk of strong contamination of the charging device by dirt in the air or on the battery pack (for example on account of prior use) by virtue of a closed air guiding channel being formed in the charging housing of the charging device. By virtue of a preferably fully circumferentially closed air guiding channel preferably extending along the entire distance between at least one charging air supply opening and at least one charging air discharge opening in the charging housing, it can be ensured that the air initially guided through the battery pack and subsequently flowing through the charging device does not contaminate any sensitive components of the charging device, in particular the charging electronics thereof. Components of the charging device in the interior of the charging housing can be completely decoupled or shielded from the cooling air flow by means of the fully circumferentially closed air guiding channel. Even if the air flow contains dirt, it cannot have a negative influence on sensitive components of the charging device. As a result, it is possible to enable rapid and reliable charging of a battery pack by means of a charging device in which components are reliably protected against excessive contamination.

It is particularly advantageous if a charging device having the described functions is operated in combination with a battery pack whose battery pack housing is equipped with at least one battery air supply opening and with at least one battery air discharge opening, between which the air conveying device of the charging device can suck air through in order to cool the battery pack. Even if the air sucked through the battery pack (for example in a construction site environment) is dirt-laden, the above-described closed air guiding channel of the charging device can reliably avoid undesired contamination of critical components of the charging device. In order to further dampen the development of dirt and also to protect the interior of the battery pack from excessive contamination as a result of dirt-laden cooling air, a dirt collecting pocket can be connected to the battery pack air supply opening in the battery pack in order to intercept at least some of the dirt and collect it in the dirt collecting pocket as soon as possibly dirt-laden ambient air flows through at least one battery pack supply opening of the battery pack housing.

Additional exemplary embodiments of the charging device, of the charging arrangement, of the battery pack and of the method are described below.

According to an exemplary embodiment, the air conveying device can be configured to suck in air and to push out the sucked-in air. By configuring and arranging the air conveying device for sucking in ambient air through the battery pack and subsequently through the charging device, the air-cooled battery pack can be kept free of active cooling components and thus be formed in a simple manner. Clearly, the battery pack behaves like a passive cooling object to which electrical energy is supplied during charging operation.

According to an exemplary embodiment, the air conveying device can comprise a radial fan. Such a radial fan can be configured to convey axially inflowing air and to output it radially or laterally. Clearly, a radial fan can be a fan which sucks in air axially (in particular parallel to an axis of rotation of an impeller of the radial fan) and then blows it out again offset by 90°, thus radially. Thus, the configuration of the air conveying device as a radial fan conveys a configuration desired according to a preferred embodiment, in which air at a main surface (for example a top side) of the charging device is to flow in vertically out of the battery pack block and after diversion by means of the radial fan is to escape laterally from the charging device.

According to an exemplary embodiment, the air conveying device can comprise, alternatively or in addition to a radial fan, another fan, in particular an axial fan. If an axial fan is provided, it can be combined with a deflection device for deflecting a direction of the air flow.

According to an exemplary embodiment, the charging device can comprise at least one moulded part with a closed lateral surface in the charging housing which delimits the air guiding channel. Such a moulded part can, for example, be produced cost-effectively from plastic, for example as an injection-moulded part. Said moulded part can be closed laterally over the entire circumference in order to define the air guiding channel. The air guiding channel defined by means of such a moulded part can be curved, in particular in order to deflect cooling air flowing out substantially vertically from the battery pack block and flowing into the air guiding channel of the charging device in a substantially horizontal direction for lateral discharge from the charging device. A moulded part can be mounted in a simple manner on or in the air guiding channel of the charging device, which promotes simple assembly of the charging device.

According to an exemplary embodiment, the air guiding channel can be formed in the charging housing by means of a single moulded part or by means of precisely two moulded parts. When using a single moulded part, in particular formed as an injection-moulded part, the outlay for producing the air guiding channel is particularly low and the circumferentially closed configuration is possible with particularly high reliability with regard to airtightness. Alternatively, a plurality of moulded parts (for example three, four, five or more moulded parts) can also jointly form the air guiding channel and delimit it laterally. For example, two assemblable moulded parts can be provided, between which the air conveying device can be received and assembled in a particularly simple manner. In other words, when using precisely two moulded parts, simplified assembly of the air conveying device can be achieved.

According to an exemplary embodiment, the air conveying device can be arranged in the interior of the at least one moulded part. Clearly, the at least one moulded part can comprise a closed wall for delimiting the air guiding channel in an airtight manner and for assembling the air conveying device thereon. The moulded part can thus be configured as a multifunctional part which performs the air guidance, the dirt protection of critical components of the charging device and the assembly reception of the air conveying device.

According to an exemplary embodiment, the air guiding channel can extend from a main surface (for example a top side) of the charging housing to a side wall of the charging housing. In this case, the air guiding channel can define the entire flow channel of the cooling air through the charging device and delimit it in a fully circumferentially closed manner. Apart from the air guiding channel, which can preferably be delimited by at least one moulded part, and optionally a charging housing of the charging device, the cooling air possibly comprising dirt then does not come into contact with any further component of the charging device.

According to an exemplary embodiment, the charging device can comprise charging electronics in the charging housing. For example, the charging electronics can comprise a printed circuit board, on and/or in which electronic components for providing the charging function of the rechargeable battery module can be assembled. Such charging electronics are susceptible to foreign materials such as dirt, dust and moisture, which can have a negative influence on the functionality of the charging electronics. By means of the air guiding channel, the charging electronics positioned outside thereof can be reliably protected against dirt, dust or moisture.

According to an exemplary embodiment, the air guiding channel can be configured to completely shield the charging electronics from the conveyed air.

By providing a closed air guiding channel in the charging device, it can be made impossible for the cooling air possibly comprising foreign materials to come into direct physical contact with the sensitive charging electronics when flowing through the charging device.

According to an exemplary embodiment, the air guiding channel can be configured to completely shield an interior of the charging housing from the conveyed air. According to such a preferred configuration, with the exception of the air guiding channel and the associated air conveying device, all components of the charging device accommodated in the interior of the charging housing can be protected against undesired interaction with cooling air possibly comprising foreign materials when flowing through the charging device. Advantageously, the cooling air flowing out from the battery pack block and flowing into the charging device can interact exclusively with the closed air guiding channel and the associated air conveying device when flowing through the charging device and can be shielded from all other internal components of the charging device.

According to an exemplary embodiment, the charging housing can comprise at least one charging air supply opening and at least one charging air discharge opening and can be configured such that by means of the air conveying device air can be guided out of the rechargeable battery block through the at least one charging air supply opening into the air guiding channel, through the interior of the air guiding channel and through the at least one charging air discharge opening out of the air guiding channel. Preferably, the at least one charging air supply opening can be arranged on the receiving device for receiving the battery pack on the charging device. For example, recesses in the charging housing on the receiving device can comprise a plurality of electrically conductive electrical contacts and a respectively associated charging air supply opening. This ensures that a battery pack received on the receiving device for charging is brought into operative connection with the at least one charging air supply opening without further user activity. The closed air guiding channel can directly adjoin the at least one charging air supply opening and extend as far as the at least one charging air discharge opening through the interior of the charging device.

According to an exemplary embodiment, the at least one charging air supply opening can be arranged on a top side of the charging housing and the at least one charging air discharge opening can be arranged on a side wall of the charging housing. Owing to the provision of the at least one charging air supply opening on a top side of the charging housing, preferably on the receiving device for receiving the battery pack for charging, the cooling air to be sucked through the battery pack can be conveyed by means of the air conveying device arranged in the interior of the charging housing through the battery pack and subsequently through the charging device without further measure. By means of the at least one charging air discharge opening on a side wall, in particular on a side wall of the charging device facing away from a user during operation, efficient discharge of the heated cooling air from the charging device can be ensured, which counteracts overheating of the charging device.

According to an exemplary embodiment, the charging housing can comprise no further opening apart from the at least one charging air supply opening and the at least one charging air discharge opening. Apart from said openings for guiding through the cooling air for cooling the battery pack, the charging housing can thus be closed continuously towards the outside and therefore reliably shield the charging electronics arranged in its interior against environmental influences. In particular, apart from said openings, the charging housing can be hermetically closed.

A person skilled in the art will understand that a charging housing without further openings is understood to mean a charging housing in which, apart from the at least one charging air supply opening and the at least one charging air discharge opening, no further opening of significant size is present which exposes the interior of the charging housing to environmental influences in a significant manner. Thus, due to assembly, production or tolerances, very small gaps can be formed between an upper shell and a lower shell of the charging housing, which gaps will not be understood by a person skilled in the art as a further opening in the charging housing. A mini-bore (the area of which can make up no more than 0.01% of the total area of the charging housing) for escape of condensate will also not be understood by a person skilled in the art as a further opening in the charging housing.

According to a preferred embodiment, the closed air guiding channel can enclose the air conveying device in the interior of the air guiding channel and exclude an entire remaining interior of the charging housing (including, for example, charging electronics arranged in the remaining interior of the charging housing) from the passage of the air. As a result, the air flow never comes into direct interaction with the entire remaining interior of the charging housing, but only with the closed interior of the air guiding channel. This brings about excellent dirt protection of sensitive components which can be arranged in a calmed region without air flow.

According to an exemplary embodiment, the battery pack can comprise a battery housing with at least one battery air supply opening and with at least one battery air discharge opening and can be configured such that by means of the air conveying device air can be guided or conveyed through the at least one battery air supply opening into the battery housing, through the interior of the battery housing and through the at least one battery air discharge opening out of the battery housing and into the charging device. Preferably, the at least one battery air discharge opening can adjoin the receiving device of the charging device for receiving the battery pack when the battery pack for charging is assembled there. For example, recesses in the battery housing can comprise a plurality of electrically conductive electrical contacts and a respectively associated battery air discharge opening. This ensures that a battery pack received on the receiving device of the charging device for charging is brought into operative connection with the at least one charging air supply opening without further user activity.

According to an exemplary embodiment, the at least one battery air supply opening can be arranged at a side wall of the battery housing and the at least one battery air discharge opening can be arranged at a main surface (for example a bottom side) of the battery housing. Between the at least one battery air supply opening and the at least one battery air discharge opening, the cooling air in the interior of the battery housing can flow along components to be cooled, in particular along battery electronics and along battery cells in the interior of the battery housing which are charged by a charging current of the charging device and thereby heat up. Adjacent to the at least one suction-side battery air supply opening, a dirt collecting pocket can adjoin, past which the cooling air flows and in the process is at least partially freed of foreign materials such as dirt. Such foreign materials collect automatically in the dirt collecting pocket, which can simply be emptied by a user.

According to an exemplary embodiment, the at least one battery air discharge opening and the electrical contacts can be arranged next to one another at a main surface (for example a bottom side) of the battery housing such that the air is guided past the electrical contacts. Clearly, the cooling air can flow between the corresponding electrical contacts of the battery pack and of the charging device through the above-described openings of the battery pack and of the charging device, which leads to a well-defined cooling air path and to fault-resistant handling by a user.

According to an exemplary embodiment, the at least one battery air supply opening can be arranged at a side wall of the battery housing. Ambient air can be reliably sucked in at a side wall of the battery housing without there being the risk of the at least one air supply opening being undesirably covered.

According to an exemplary embodiment, dirt guided into the battery housing with the air can be collected in a dirt collecting pocket in the battery housing when the air is guided through the battery pack. If the dirt collecting pocket is arranged on the air inlet side in the battery pack, air comprising dirt can be cleaned off as soon as it flows into the battery pack. As a result, the interior of the battery housing can also be protected against contamination.

According to an exemplary embodiment, in the charging arrangement the battery pack can comprise a closed battery housing (i.e. without battery air supply openings and without battery air discharge openings) and can be configured such that by means of the air conveying device of the charging device air is guided at least partially past the battery pack. The charging device can thus advantageously also be operated with conventional or non-ventilated battery packs, wherein the air conveyed by means of the air conveying device can cool the battery pack to a certain extent.

Exemplary embodiments of the present disclosure are described in detail below with reference to the following figures.

### BRIEF DESCRIPTION OF THE DRAWINGS

FIG. 1 shows a cross-sectional view of a charging arrangement comprising a charging device and a battery pack according to an exemplary embodiment of the disclosure.

FIG. 2 shows a spatial view of a charging arrangement comprising a charging device and a battery pack according to another exemplary embodiment of the disclosure.

FIG. 3, FIG. 4, FIG. 5, FIG. 6 andFIG. 7 show different views of a charging arrangement comprising a charging device and a battery pack according to a further exemplary embodiment of the disclosure.

FIG. 8 shows a cross-sectional view of a battery pack according to an exemplary embodiment of the disclosure.

### DETAILED DESCRIPTION OF THE DRAWINGS

Identical or similar components in different figures are provided with identical reference numerals.

Before exemplary embodiments of the disclosure are described with reference to the figures, some general aspects of exemplary embodiments of the disclosure will still be explained.

According to an exemplary embodiment, a charging device for an exchangeable and rechargeable battery pack of a hand-held device (for example an electric drilling machine) is provided. The discharged battery pack to be recharged is assembled on a receiving device of the charging device and thereby electrically coupled thereto. In order to cool the battery pack by means of an air flow, the charging device can be equipped with an air conveying device. In a state of the battery pack assembled on the charging device, the air conveying device can firstly convey air through the battery pack and then along a circumferentially closed air guiding channel in a charging housing of the charging device. For this purpose, the air conveying device can suck in ambient air in the charging device and convey it out of the battery pack through at least one battery pack supply opening, through the battery pack and through at least one battery pack discharge opening. The at least one battery pack discharge opening is aligned with at least one charging supply opening of the charging device when the battery pack is assembled on the charging device. The cooling air conveyed out of the at least one battery pack air discharge opening thereby passes into the at least one charging air supply opening, through the closed air guiding channel passing through the charging device in an airtight manner and through at least one charging air discharge opening on the output side out of the charging device back to the surroundings. In this case, the air conveying device is preferably arranged in the interior of the closed air guiding channel. On account of this configuration, the interior of the battery pack can be subjected to air cooling in a defined manner, during and/or before the charging process is carried out. Rapid charging can thereby be brought about without the risk of overheating of the battery pack. Advantageously, it can thereby be simultaneously avoided that dirt from the ambient air or from the battery pack passes into critical regions in the interior of the charging device. Such critical regions, in particular charging electronics in the interior of a charging housing, can namely be kept separated from the cooling air flow by means of the closed air guiding channel. Rapid and fault-resistant charging of a battery pack by means of a charging device can thus be achieved.

Effective dirt protection during the electrical charging of a battery pack by a charging device can alternatively or additionally be achieved in that the battery pack is provided with at least one dirt collecting pocket between its at least one battery air supply opening and its at least one battery air discharge opening. Preferably, this is provided in the region of the at least one battery air supply opening in order to at least partially separate dirt from sucked-in ambient air fully at the start of the guided air path through battery pack and charging device and accumulate it in the dirt collecting pocket. On account of its spatial proximity to the at least one battery air supply opening, it is also possible in a simple manner for a user to easily empty separated dirt from the dirt collecting pocket.

Clearly, according to one exemplary embodiment of the disclosure, a battery pack (also referred to as battery pack or battery module) can be provided which is configured in cooperation with a charging device with air conveying device by means of a type of injector principle for the air conveying. A flow through the battery pack can thereby be brought about directly with a fan air flow. Advantageously, air channel guidance can be achieved in a closed manner within an outer shell of the charger and outside an electronics installation space of the charger via a geometric channel separation.

Before and/or during a charging process for charging a battery pack by means of a charging device, the battery pack can be air-cooled. A closed air guiding channel in the charging device can clearly prevent dirt transported with the cooling air flow from coming into contact with sensitive components (in particular charging electronics) of the charging device. The charging device preferably comprises an air conveying device configured as a fan for accelerating the charging process by efficient cooling of the battery pack. When a completely or partially emptied battery pack comes from an application (for example sawing of wooden beams), in which the battery pack has supplied a power hand-held device (for example a motorized saw) with electrical drive energy, a charging of the battery pack can require that the battery pack is first cooled down from its operating temperature before the start of the charging process. Furthermore, a heat development also occurs during a charging of a battery pack by means of a charging device. In order to dissipate heat from the battery pack, the charging device sucks in air through the battery pack and the charging device itself. In this case, a fan of the charging device can also suck in dirt on the battery or the ambient air, which is at least partially guided with the cooling air through the battery pack and subsequently through a closed cooling channel in the charging device. By virtue of a closed cooling channel being formed in the charging device, the dirt is guided through the charging device without remaining to a greater extent in the charging device or impairing critical components of the charging device (in particular charging electronics).

If a dirt collecting pocket is provided on the air inlet side on the battery pack, at which dirt collecting pocket said air discharges at least part of its dirt before it is sucked further through the battery pack, the dirt protection of rechargeable battery module and charging device can be further improved. Such a dirt collecting pocket can guide the air sucked in through the at least one battery air supply opening along a complex-shaped air path in an air inlet-side section of the battery pack (for example along a labyrinth of wall sections) in order to bring about efficient dirt depletion of the contaminated air. The arrangement of the dirt collecting pocket on an air inlet side of the battery pack can advantageously have the effect that the dirt does not collect in a manner distributed over the entire battery pack.

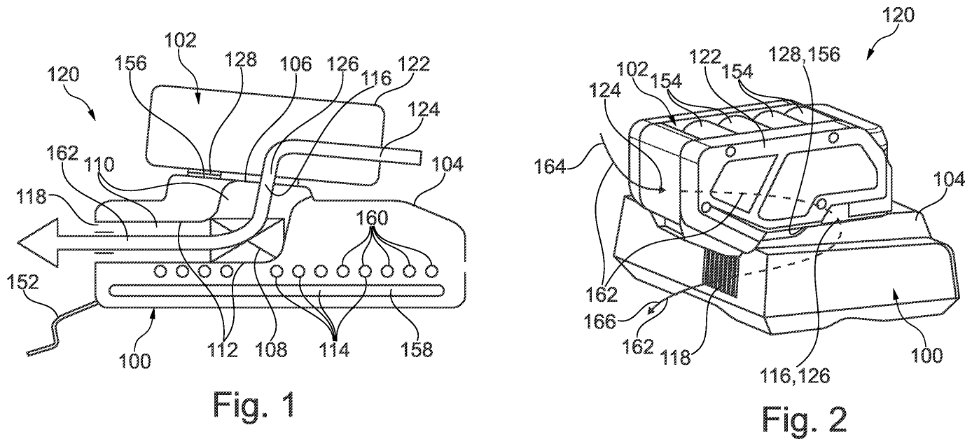

FIG. 1 shows a cross-sectional view of a charging arrangement 120 comprising a charging device 100 and a battery pack 102 according to an exemplary embodiment of the disclosure.

The battery pack 102 can supply a power hand-held device, not shown, with electrical energy during operation. For this purpose, the battery pack 102 can be plugged into the power hand-held device in its charged state, as a result of which the power hand-held device can be operated wirelessly. After discharging the battery pack 102, the latter can be recharged.

For charging a completely or partially discharged battery pack 102, the charging device 100 is used, which can be connected to a power grid, for example plugged into a socket, for supplying electrical energy by means of a cable 152. For charging the battery pack 102, the battery pack 102 is electromechanically received on a receiving device 106 of the charging device 100. In other words, placing the battery pack 102 onto the receiving device 106 by a user can simultaneously bring about a positively locking mechanical connection and an electrically conductive connection between the battery pack 102 and the charging device 100.

In order to cool the battery pack 102 during electrical charging, ambient air is sucked in by means of an air conveying device 108, preferably configured as a radial fan, in the interior of a closed air guiding channel 110 of the charging device 100 through the battery pack 102 and then through the interior of the air guiding channel 110 upstream of the air conveying device 108 or is ejected downstream of the air conveying device 108.

Said charging device 100 comprises an outer charging housing 104 formed, for example, from plastic. On an upper outer side of the charging housing 104, the receiving device 106 for receiving the battery pack 102 for charging is formed, on which receiving device in particular a plurality of electrical contacts 156 of the charging device 100 are provided for forming an electrically conductive connection with electrically conductive electrical contacts 128 of the battery pack 102. For example, the electrical contacts 128 of the battery pack 102 can comprise two charging contacts (for example a positive pole and a negative pole). Furthermore, the electrical contacts 128 of the battery pack 102 can comprise at least one current tapping contact for tapping current through a hand-held device. Furthermore, it is possible that the electrical contacts 128 of the battery pack 102 comprise at least one (for example two) communication contacts.

Furthermore, the air conveying device 108 configured as a radial fan is arranged in an interior of the air guiding channel 110 for conveying air through the charging device 100. Advantageously, in the interior of the charging housing 104, a fully circumferentially closed air guiding channel 110 is delimited which extends from the receiving device 106 through an interior of the charging housing 104. By means of the air conveying device 108, when the battery pack 102 is received on the receiving device 106 for charging, air can be conveyed through the battery pack 102 along a defined continuous air guiding path and conveyed through the interior of the air guiding channel 110.

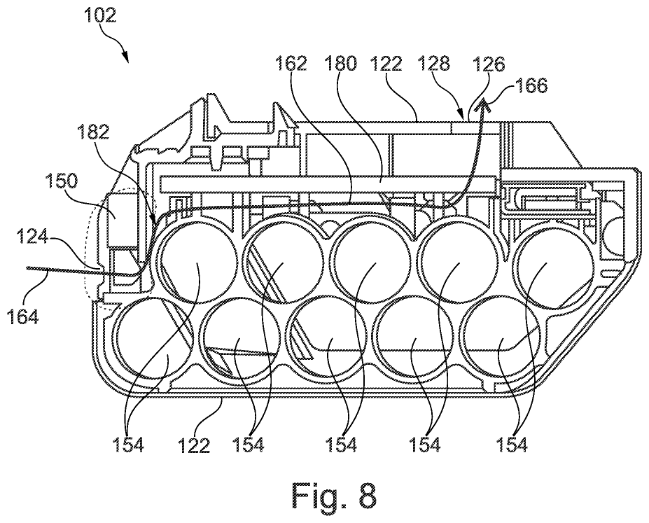

As already mentioned, the illustrated battery pack 102 can be removably mounted on a power hand-held device, not shown, in order to supply the power hand-held device wirelessly with electrical energy. For this purpose, a plurality of battery cells are located in the interior of the battery pack 102, which battery cells are illustrated in FIG. 8 with reference numeral 154. When the battery cells 154 are emptied after supplying the power hand-held device with electrical energy, they can be recharged by means of the illustrated charging device 100.

The battery pack 102 according to FIG. 1 comprises the electrical contacts 128 already mentioned above for charging the battery pack 102 when the battery pack 102 is received on the receiving device 106 of the charging device 100 and the electrical contacts 128 are thereby brought into electrically conductive contact with the corresponding electrical contacts 156 of the charging device 100.

An outer contour of the battery pack 102 is defined by a battery pack housing 122 preferably formed from plastic. On a side wall of the battery pack housing 122, a battery air supply opening 124 is formed, through which ambient air can be sucked into the interior of the battery pack 102. Furthermore, an underside of the battery pack housing 122 is provided with a battery air discharge opening 126. The battery air discharge opening 126 and the electrical contacts 128 can be arranged next to one another at an underside of the battery pack housing 122 such that the air is guided past the electrical contacts 128. The battery air discharge opening 126 is positioned such that during charging of the battery pack 102 mounted on the receiving device 106 by means of the air conveying device 108 of the charging device 100 air is guided through the battery air supply opening 124 into the battery pack housing 122, through the interior of the battery pack housing 122, through the battery air discharge opening 126 out of the battery pack housing 122, through a charging air supply opening 116 of the charging device 100 into the closed air guiding channel 110 of the charging device 100 and from there through a charging air discharge opening 118 out of the charging device 100. The entire air conveying from the battery air supply opening 124 to the charging air discharge opening 118 is brought about by the air conveying device 108, so that the battery pack 102 can be free of an air-conveying device and can thus be formed in a particularly simple manner.

By the air conveying device 108 shown in FIG. 1 being configured as a radial fan, the cooling air sucked in substantially perpendicularly into the charging device 100 can be deflected in a substantially horizontal direction without further measures and can thereby be guided out laterally from the charging device 100.

Advantageously, the circumferentially closed air guiding channel 110 is formed in the interior of the charging housing 104 by a moulded part 112 with a closed lateral surface configured, for example, as a plastic injection-moulded part. This moulded part 112 receives the air conveying device 108 and can be simply inserted into the charging housing 104 in order to delimit the air guiding channel 110. In a particularly simple configuration, the air guiding channel 110 can be formed in the charging housing 104 by means of a single curved or bent moulded part 112. A configuration of the closed air guiding channel 110 from two moulded parts 112 to be placed one on top of the other, between which the air conveying device 108 can be assembled, can also be simple in terms of production technology. The air conveying device 108 can thus be arranged and fastened in the interior of the at least one moulded part 112. As shown in FIG. 1, the curved and laterally fully circumferentially closed air guiding channel 110 extends from a top side of the charging housing 104 to a side wall of the charging housing 104.

Charging electronics 114 of the charging device 100 are likewise arranged in the interior of the charging housing 104, but outside the closed air guiding channel 110 and fluidically decoupled therefrom. The charging electronics 114 are used to control the process of charging the rechargeable battery module 102 by means of the charging device 100 and to provide electrical energy to the rechargeable battery module 102. In the exemplary embodiment shown, the charging electronics 114 comprise a printed circuit board 158 (PCB). Shown schematically in FIG. 1 are electronic components 160 of the charging electronics 114, which can be surface-mounted on the printed circuit board 158. For example, such electronic components comprise passive components (for example resistors, capacitors, inductances) and/or active components (for example at least one semiconductor chip). The charging electronics 114 described can be dirt-sensitive. It is therefore particularly advantageous for the air guiding channel 110 guiding the optionally dirt-laden cooling air to be configured completely separately from and without fluid connection with the charging electronics 114. This configuration ensures that the charging electronics 114 in the interior of the charging housing 104 are completely shielded from the air conveyed by the closed air guiding channel 110. Furthermore, the fully circumferentially closed air guiding channel 110 is preferably configured to completely shield or completely partition off an entire remaining interior of the charging housing 104 from the conveyed cooling air in the cooling air path 162.

According to FIG. 1, the charging device 100 is thus equipped with the air conveying device 108 configured as a fan and the moulded part 112 configured as an insert part which moulds the closed air guiding channel 110 and keeps the air flow away from the charging electronics 114 in the electronics installation space within the charging housing 104. Advantageously, the closed air guiding channel 110 encloses only the air conveying device 108 in the interior of the air guiding channel 110. By contrast, the closed air guiding channel 110 excludes an entire remaining interior of the charging housing 104, and in this case in particular the charging electronics 114 arranged in the remaining interior of the charging housing 104, from the passage of the air. In other words, the charging electronics 114 are consequently never located in the air flow, but in a region shaded thereby.

During the charging process, in particular the rechargeable battery block 102 heats up and is effectively cooled by means of the described air cooling. The charging electronics 114 of the charging device 100 heat up only moderately during charging and therefore does not require direct cooling. However, the charging electronics 114 can be cooled indirectly.

FIG. 2 shows a spatial view of a charging arrangement 120 comprising a charging device 100 and a battery pack 102 according to another exemplary embodiment of the disclosure.

FIG. 2 shows in particular the sucked-in cool ambient air 164, which can flow into the battery pack housing 122 for example through two lateral battery air supply openings 124. FIG. 2 furthermore shows the heated air 166 pushed out of the charging housing 104, which can exit from the battery pack housing 122 for example through lateral charging air discharge openings 118. In the interior of the battery pack 102 and in the interior of the charging device 100, the cooling air path 162 is curved substantially in a U-shaped manner, which promotes efficient supply and discharge of the air and leads to effective cooling in the interior of the battery pack 102.

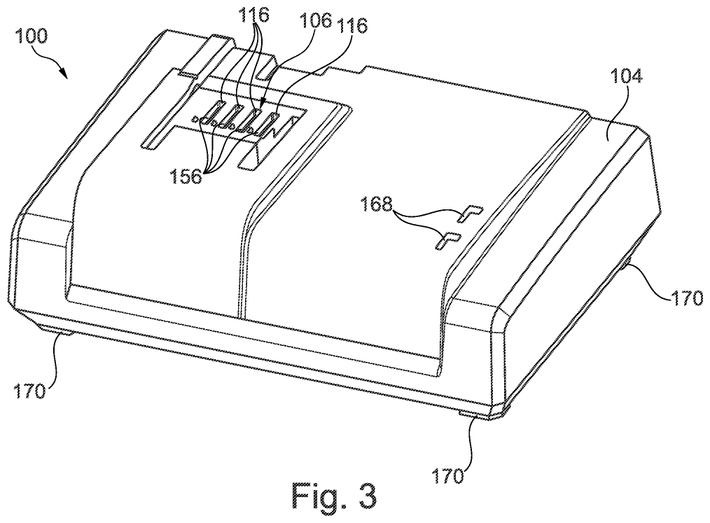

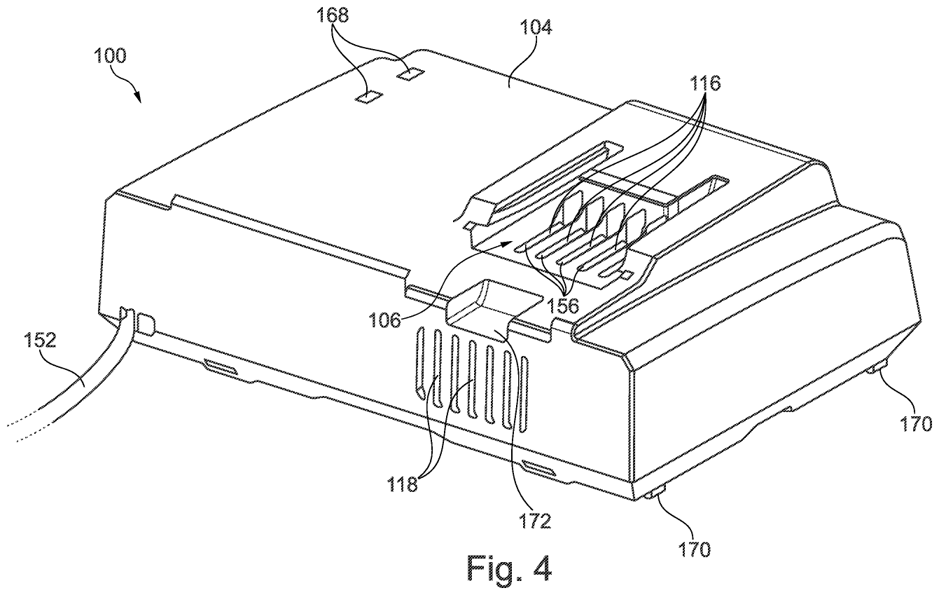

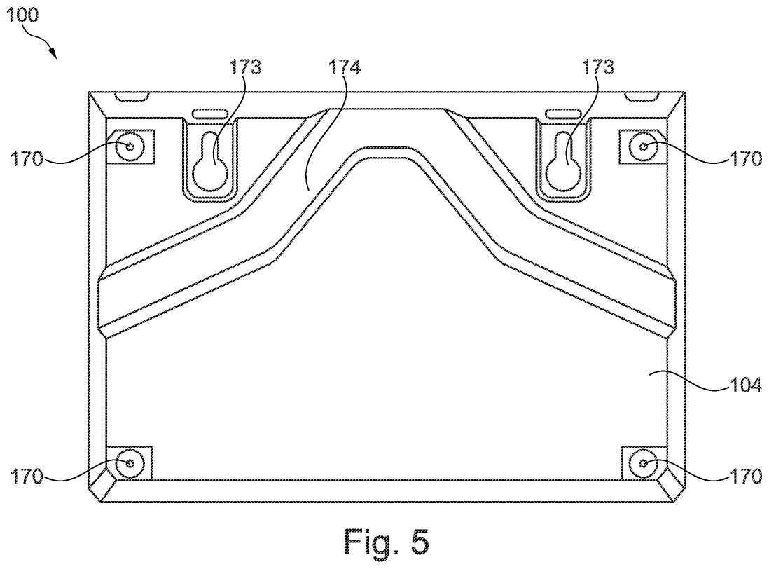

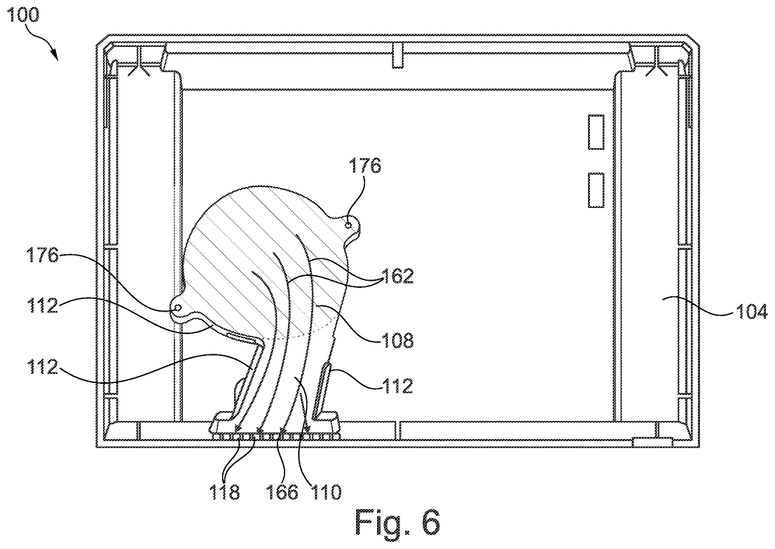

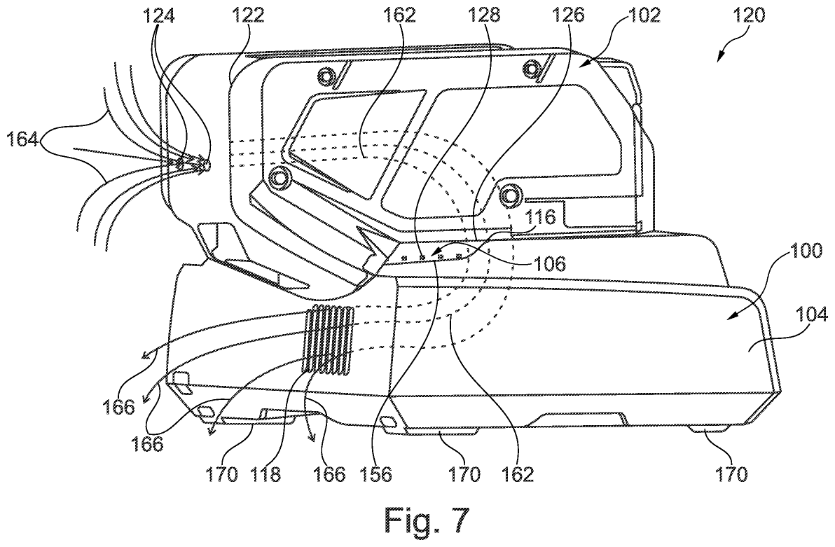

FIGS. 3 to 7 show different views of a charging arrangement 120 comprising a charging device 100 and a battery pack 102 according to a further exemplary embodiment of the disclosure. FIG. 3 shows a spatial view of the charging device 100 from a front side, from which a user attaches a battery pack 102 to the charging device 100 for charging during operation. FIG. 4 illustrates the charging device 100 in a further spatial view from a rear side, which faces away from a user during handling. FIG. 5 shows a bottom side of the charging device 100. FIG. 6 illustrates an upper shell of a charging housing 104 of the charging device 100 after removal of a base part of the charging housing 104.

FIG. 7 is a spatial side view of the charging device 100 and the battery pack 102 assembled thereon.

FIG. 3 shows details of the receiving device 106 for positively locking receiving of the battery pack 102 while forming an electrically conductive connection between the electrical contacts 128, 156. For example, the electrical contacts 156 of the receiving device 106 can be configured as electrical spring contacts past which air flows through the charging air supply openings 116. For example, four or five electrical contacts 156 can be provided. Optical display devices 168, which can be formed, for example, by light-emitting diodes, can display a state of the charging device 100 and a charging state. Feet 170 can be mounted on the base of the charging housing 104. For example, four feet 170 can be provided, two of which can be equipped with an anti-slip device (for example a rubber element).

FIG. 4 shows that a cable 152 for supplying the charging device 100 with electrical energy can be guided out of the charging housing 104 from a power grid. A notch 172 on a top side of the charging housing 104 is used for positively locking receiving of the battery pack 102 without locking on the charging device 100.

FIG. 5 shows provisions 173 for optional wall mounting of the charging device 100. Furthermore, FIG. 5 shows a V-shaped depression 174 on the base, which is used for guided receiving of a cable.

FIG. 6 shows a view from below into the upper shell of the charging device 100, which shows the closed air guiding channel 110. In this case, it is particularly advantageous for the air guiding channel 110 to be completely separated and partitioned off from the interior of the charging device 100, in particular from the charging electronics 114 not shown in FIG. 6. Clearly, air can flow perpendicularly to the paper plane of FIG. 6 and can be blown out laterally by means of the air conveying device 108 configured as a radial fan, as shown in FIG. 6. The air conveying device 108 assembled in the closed air guiding channel 110 can be mounted by means of two screw fastenings 176.

FIG. 7 once again shows the cooling air path 162 along which fresh, cold ambient air 164 is converted into heated air 166, i.e. heated exhaust air.

FIG. 8 shows a cross-sectional view of a battery pack 102 according to an exemplary embodiment of the disclosure.

The battery pack 102 shown in FIG. 8 is advantageously provided with a dirt collecting pocket 150 in the battery pack housing 122. If possibly dirt-laden ambient air, sucked in by the air conveying device 108, not shown in FIG. 8, of a corresponding charging device 100 flows through the at least one battery air supply opening 124 into the battery pack housing 122, the air is deflected at the dirt collecting pocket 150 (in particular from a substantially horizontal flow direction into a substantially vertical flow direction and back again into a substantially horizontal flow direction). The battery pack 102 in the form of housing-inner wall sections thus comprises an air deflection labyrinth 182 for deflecting the air for conveying separation of dirt at the dirt collecting pocket 150. By means of such an air inlet-side labyrinth system, dirt can be separated from the air and collected in the dirt collecting pocket 150. The at least partially cleaned air then flows through the interior of the battery pack housing 122 and cools the components arranged there. Since the dirt collecting pocket 150 is arranged directly adjacent to the battery air supply opening 124, dirt guided into the battery pack housing 122 with the air can be separated at an early stage, as a result of which excessive contamination in the interior of the battery pack housing 122 can be avoided. Dirt guided into the battery pack housing 122 with the air can thus be collected in the dirt collecting pocket 150 in the battery pack housing 122 when the air is guided through the battery pack 102 and emptied by a user.

As shown in FIG. 8, the cooling air can be guided between the battery cells 154 and a printed circuit board 180, on which electronic components can be mounted (not shown). As a result, the battery cells 154 and the battery electronics can be cooled.

In addition, it should be noted that “comprising” does not exclude any other elements or steps and “a” or “an” does not exclude a plurality. Furthermore, it should be noted that features or steps which have been described with reference to one of the above exemplary embodiments can also be used in combination with other features or steps of other exemplary embodiments described above. Reference numerals in the claims should not be regarded as a restriction.

1.-17. (canceled)

18. A charging device for charging a battery pack for a hand-held device, the charging device comprising:
a charging housing;
a receiving device provided on the charging housing for receiving the battery pack for charging;
an air conveying device in and/or on the charging housing for conveying air; and
a closed air guiding channel which extends from the receiving device through an interior of the charging housing, so that air can be guided through the battery pack and/or past the battery pack and through the interior of the air guiding channel by means of the air conveying device;
wherein the air guiding channel is formed in the charging housing by means of a single moulded part or by means of precisely two moulded parts, wherein the charging device comprises at least one moulded part with a closed lateral surface in the charging housing which delimits the air guiding channel;
wherein the air conveying device is arranged in the interior of the at least one moulded part.

19. The charging device according to claim 18, wherein the air conveying device is configured to suck in air and to push out the sucked-in air.

20. The charging device according to claim 18, wherein the air conveying device comprises a radial fan.

21. The charging device according to claim 18, wherein the air guiding channel extends from a main surface, for example a battery receiving surface or a top side, of the charging housing to a side wall of the charging housing.

22. The charging device according to claim 18, comprising charging electronics in the charging housing.

23. The charging device according to claim 22, wherein the air guiding channel is configured to completely shield the charging electronics from the conveyed air.

24. The charging device according to claim 18, wherein the air guiding channel is configured to completely shield an interior of the charging housing from the conveyed air.

25. The charging device according to claim 18, wherein the charging housing comprises at least one charging air supply opening and at least one charging air discharge opening and is configured such that by means of the air conveying device air can be guided out of the rechargeable battery block and/or at the rechargeable battery block through the at least one charging air supply opening into the air guiding channel, through the interior of the air guiding channel and through the at least one charging air discharge opening out of the air guiding channel.

26. The charging device according to claim 25, wherein the at least one charging air supply opening is arranged at a main surface, for example a battery receiving surface or a top side, of the charging housing and the at least one charging air discharge opening is arranged at a side wall of the charging housing.

27. The charging device according to claim 25, wherein the charging housing comprises no further opening apart from the at least one charging air supply opening and the at least one charging air discharge opening.

28. The charging device according to claim 18, wherein the closed air guiding channel encloses the air conveying device in the interior of the air guiding channel and excludes an entire remaining interior of the charging housing from the passage of the air.

29. A charging arrangement, comprising:
a battery pack for a hand-held device; and
a charging device according to claim 18 for charging the battery pack when the battery pack is received on the receiving device, wherein air can be guided through the battery pack and/or past the battery pack and through the interior of the air guiding channel by means of the air conveying device.

30. The charging arrangement according to claim 29, wherein the battery pack comprises a battery housing with at least one battery air supply opening and with at least one battery air discharge opening and is configured such that by means of the air conveying device air can be guided through the at least one battery air supply opening into the battery housing, through the interior of the battery housing and through the at least one battery air discharge opening out of the battery housing and into the charging device.

31. The charging arrangement according to claim 30, wherein the at least one battery air supply opening is arranged at a side wall of the battery housing and the at least one battery air discharge opening is arranged at a main surface, for example a charging side or a bottom side, of the battery housing.

32. The charging arrangement according to claim 29, wherein the battery pack comprises a closed battery housing and is configured such that by means of the air conveying device air is guided at least partially past the battery pack.

33. A method for charging a battery pack for a hand-held device by means of a charging device according to claim 18, the method comprising:
receiving the battery pack for charging at a receiving device of the charging device provided on a charging housing; and
conveying air by means of an air conveying device of the charging device in and/or on the charging housing along a fully circumferentially closed air guiding channel which extends from the receiving device through an interior of the charging housing, so that air is guided through the battery pack and/or past the battery pack and through the interior of the air guiding channel by means of the air conveying device.

34. The method according to claim 33, wherein dirt guided into the battery housing with the air is collected in a dirt collecting pocket in the battery housing when the air is guided through the battery pack.
